(19) United States
(12) Patent Application Publication
(10) Pub. No.: US 2026/0040840 A1
(43) Pub. Date: Feb. 5, 2026

(54) METHOD OF MANUFACTURING SEMICONDUCTOR DEVICE

(71) Applicant: Samsung Electronics Co., Ltd., Suwon-si (KR)

(72) Inventors: Junho Lee, Suwon-si (KR); Sangchul Han, Suwon-si (KR); Seokhyun Kim, Suwon-si (KR); Siyeong Yang, Suwon-si (KR); Seokjun Hong, Suwon-si (KR); Yihwan Kim, Suwon-si (KR); Kwangmin Park, Suwon-si (KR)

(21) Appl. No.: 19/240,188

(22) Filed: Jun. 17, 2025

(30) Foreign Application Priority Data
Jul. 31, 2024 (KR) 10-2024-0101689

(51) Int. Cl. H01L 21/02; H10B 41/27; H10B 43/27

(52) U.S. Cl. CPC H01L 21/02672; H10B 41/27; H10B 43/27

(57) ABSTRACT

A method of manufacturing a semiconductor device includes forming a conductive layer below a plate layer, forming a molded structure on the plate layer, forming channel layers extending in the molded structure in a direction perpendicular to an upper surface of the plate layer, forming a metal layer on the channel layers, forming a metal silicide layer on respective tops of the channel layers using the metal layer, applying an electric field to crystallize the channel layers using the metal silicide layers, and removing the conductive layer.

### CROSS-REFERENCE TO RELATED APPLICATION(S)

This application claims benefit of priority under 35 U.S.C. § 119 to Korean Patent Application No. 10-2024-0101689 filed on Jul. 31, 2024 in the Korean Intellectual Property Office, the disclosure of which is incorporated herein by reference in its entirety.

### BACKGROUND

The present inventive concept relates generally to a method of manufacturing a semiconductor device.

In a data storage system that requires data storage, a semiconductor device capable of storing a large amount of data is required. Accordingly, a method for increasing data storage capacity of a semiconductor device is being researched. For example, as one of the methods for increasing the data storage capacity of a semiconductor device, a semiconductor device including memory cells arranged three-dimensionally, instead of memory cells arranged two-dimensionally, is being proposed.

### SUMMARY

An object of the present inventive concept is to provide a method of manufacturing a semiconductor device that includes crystallizing channel layers by applying an electric field thereto.

According to an aspect of the present inventive concept, a method of manufacturing a semiconductor device, may comprise: forming a conductive layer below a plate layer; forming a molded structure on the plate layer; forming channel layers penetrating (i.e., extending in) the molded structure; forming a metal layer on the channel layers; forming metal silicide layers on a top (i.e., upper surface) of each of the channel layers using the metal layer; applying an electric field to crystallize the channel layers using the metal silicide layers; and removing the conductive layer.

According to an aspect of the present inventive concept, a method of manufacturing a semiconductor device may comprise: forming a conductive layer below a plate layer; forming a molded structure on the plate layer; forming channel layers penetrating the molded structure; forming a metal silicide layer on an upper surface of each of the channel layers using the metal layer; and applying an electric field to crystallize the channel layers using the metal silicide layers, wherein applying the electric field comprises: providing a wafer comprising the plate layer on an electrostatic chuck in a plasma chamber; and applying a voltage to the electrostatic chuck and an upper electrode on the wafer to form plasma on the channel layers.

According to an aspect of the present inventive concept, a method of manufacturing a semiconductor device may comprise: forming a conductive layer below a plate layer; alternately stacking interlayer insulating layers and sacrificial insulating layers on the plate layer to form a molded structure; forming channel holes penetrating the molded structure; forming channel layers in the channel holes; forming a metal layer on the channel layers; forming a metal silicide layer on an upper surface of each of the channel layers using the metal layer; heating the channel layers; applying an electric field to crystallize the channel layers using the metal silicide layers; and removing the conductive layer. A direction of the applied electric field may be perpendicular to an upper surface of the plate layer.

### BRIEF DESCRIPTION OF DRAWINGS

The above and other aspects, features, and advantages of the present inventive concept will be more clearly understood from the following detailed description, taken in conjunction with the accompanying drawings, wherein like reference numerals (when used) indicate corresponding elements throughout the several views, and in which:

FIG. 1 is a flow chart for illustrating a method of manufacturing a semiconductor device according to an example embodiment;

FIGS. 2 to 11 are schematic vertical cross-sectional views illustrating intermediate processes in a method of manufacturing a semiconductor device according to an example embodiment in accordance with a process sequence;

FIGS. 12 to 14 are schematic views conceptually illustrating a method for crystallizing a channel layer according to an example embodiment;

FIG. 15 illustrates vertical cross-sectional transmission electron microscope (TEM) images of channel layers according to a comparative example and an example embodiment; and

FIGS. 16 and 17 are schematic vertical cross-sectional views of semiconductor devices according to example embodiments.

### DETAILED DESCRIPTION

Hereinafter, example embodiments of the present inventive concept will be described with reference to the accompanying drawings.

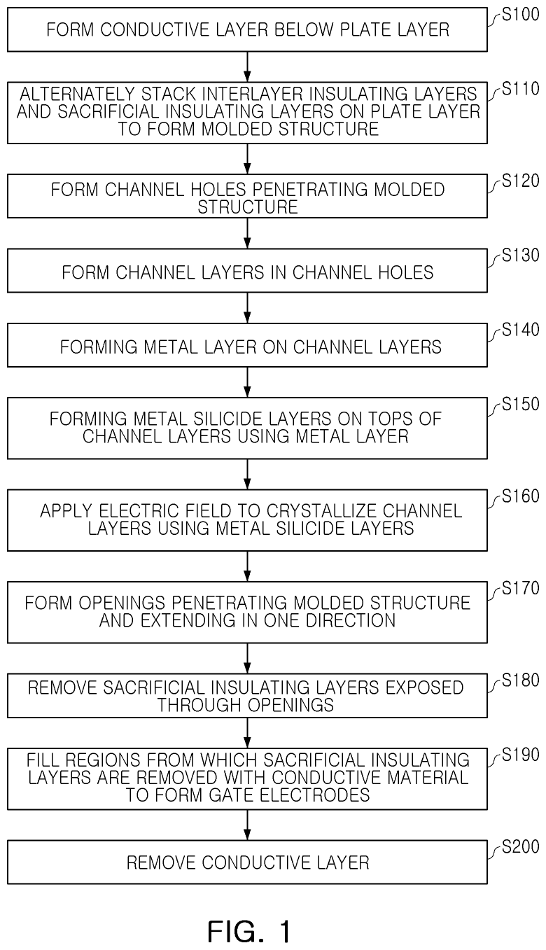

FIG. 1 is a flow chart for illustrating a method of manufacturing a semiconductor device according to an example embodiment. Referring to FIG. 1, a method of manufacturing a semiconductor device according to an embodiment of the present disclosure may include forming a conductive layer on a lower surface of a plate layer (S100), alternately stacking interlayer insulating layers and sacrificial insulating layers on the plate layer to form a molded structure (S110), forming channel holes (i.e., openings) penetrating (i.e., extending in) the molded structure (S120), forming channel layers in the channel holes (S130), forming a metal layer on the channel layers (S140), forming a metal silicide layer on an upper surface of each of the channel layers using the metal layer (S150), applying an electric field to crystallize the channel layers using the metal silicide layers (S160), forming openings penetrating the molded structure and extending in one direction (S170), removing sacrificial insulating layers exposed through the openings (S180), filling regions from which the sacrificial insulating layers are removed with a conductive material to form gate electrodes (S190), and removing the conductive layer (S200). The term “exposed” (or “exposing,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. The term “filling” (or “fill,” or like terms) is intended to refer to either completely filling a defined space (e.g., the trench for element separation) or partially filling the defined space; that is, the defined space need not be entirely filled but may, for example, be partially filled or have voids or other spaces throughout.

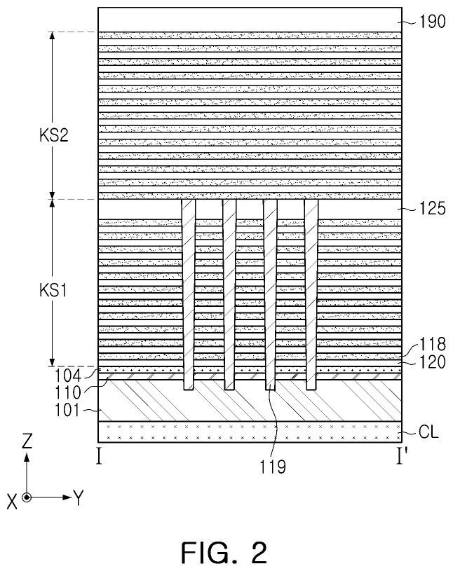

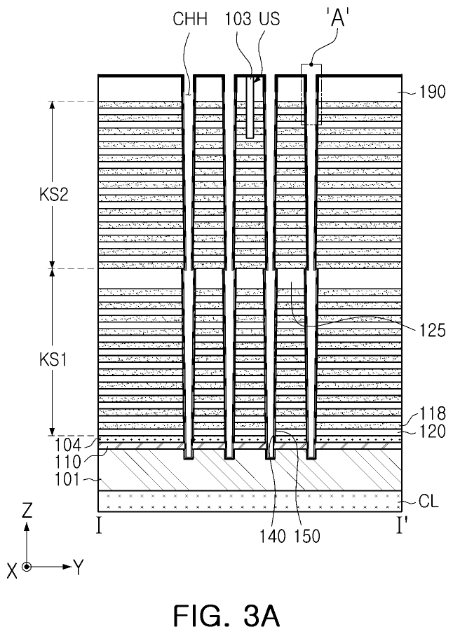

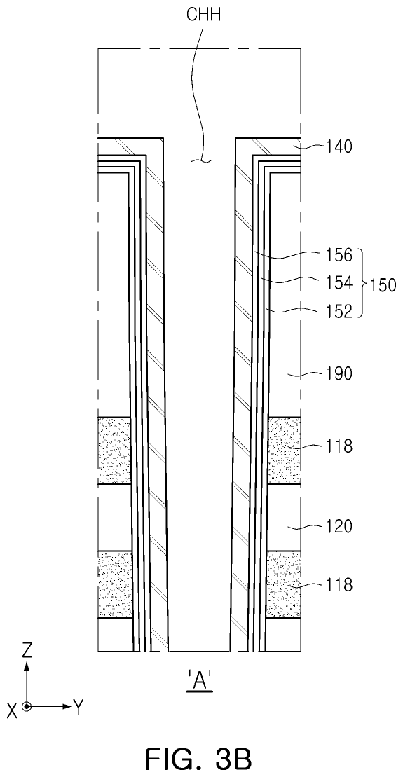

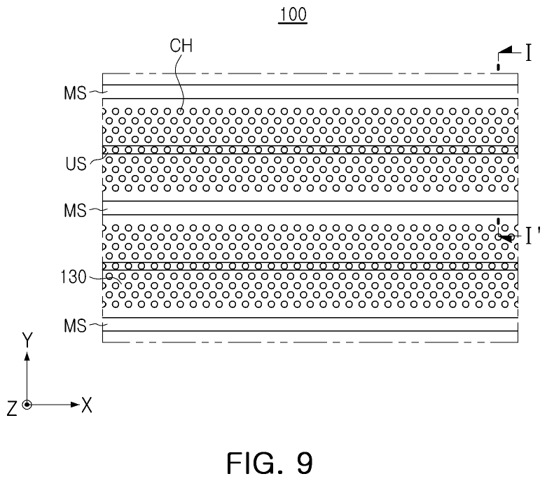

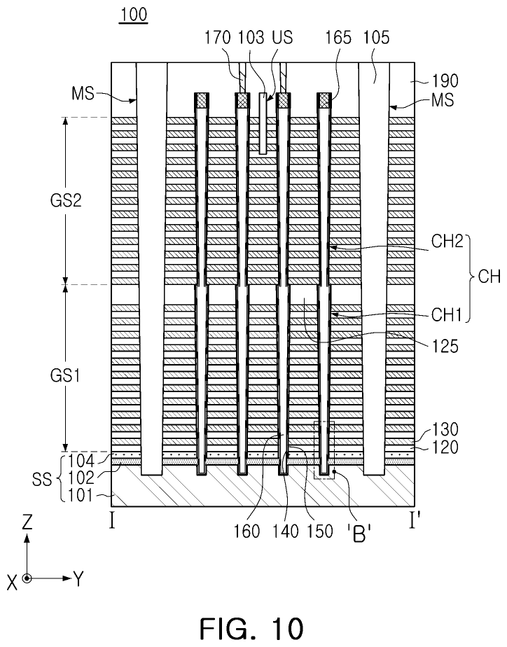

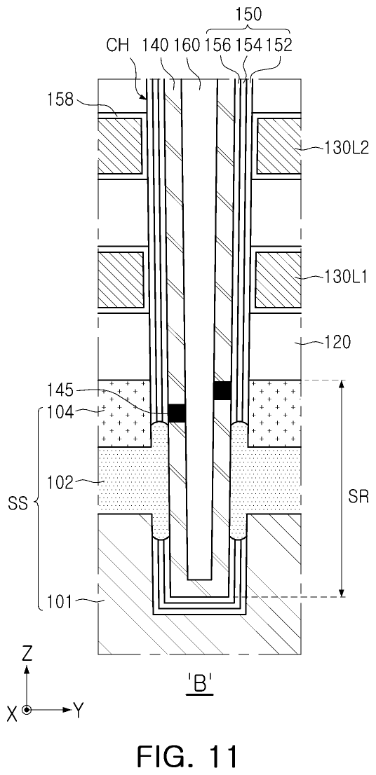

FIGS. 2 to 11 are schematic views illustrating a method of manufacturing a semiconductor device according to an example embodiment in accordance with a process sequence. FIGS. 2-8 are schematic vertical cross-sectional views depicting intermediate processes in the method of manufacturing the semiconductor device, FIG. 9 illustrates a schematic plan view of a semiconductor device after a manufacturing process has been completed, FIG. 10 is a schematic vertical cross-sectional view taken along line I-I′ of FIG. 9, and FIG. 11 is an enlarged view of a portion of FIG. 10. FIGS. 2, 3A, 4A, 5A, 6A, 7 and 8 are vertical cross-sectional views corresponding to FIG. 10. FIGS. 3B, 4B, 5B and 6B are enlarged views of portions of FIGS. 3A, 4A, 5A and 6A, respectively, and may correspond to region A thereof.

Referring to FIGS. 1 and 2, a conductive layer CL may be formed below a plate layer 101 (S100), and sacrificial insulating layers 118 and interlayer insulating layers 120 may be alternately stacked in a Z-direction (i.e., vertical direction), perpendicular to an upper surface of the conductive layer CL, to form first and second molded structures KS1 and KS2 (S110).

The plate layer 101 may have an upper surface extending in an X-direction and a Y-direction (i.e., in a horizontal plane). The plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may also be provided as a bulk wafer, an epitaxial layer, a silicon on insulator (SOI) layer, or a semiconductor on insulator (SeOI) layer, although embodiments are not limited thereto.

The conductive layer CL may be formed by depositing a conductive material on a lower surface of the plate layer 101 or doping impurities on the lower surface of the plate layer 101. The conductive layer CL may include at least one of a metal, a conductive metal nitride, or a semiconductor material doped with impurities, although embodiments are not limited thereto. The metal may include, for example, at least one of titanium (Ti), tantalum (Ta), tungsten (W), copper (Cu), or aluminum (Al). The metal nitride may include at least one of titanium nitride (TiN), tantalum nitride (TaN), or tungsten nitride (WN), although embodiments are not limited thereto. The impurities may be N-type impurities and/or P-type impurities.

A horizontal sacrificial layer 110 and a first horizontal conductive layer 104 may be first formed on the plate layer 101, then a first molded structure KS1 may be formed, then vertical sacrificial layers 119 penetrating (i.e., extending in) the first molded structure KS1 in the Z-direction may be formed, and the second molded structure KS2 may be formed on the first molded structure KS1.

The horizontal sacrificial layer 110 may include a plurality of layers including different materials. The horizontal sacrificial layer 110 may be layers that will be replaced with a second horizontal conductive layer 102 (see FIG. 11) through a subsequent process. For example, the horizontal sacrificial layer 110 may include a first layer and a third layer made of the same material as the interlayer insulating layers 120, and may further include a second layer made of the same material as the sacrificial insulating layers 118 and disposed between the first layer and the third layer. The first horizontal conductive layer 104 may be formed on the horizontal sacrificial layer 110.

The sacrificial insulating layers 118 may be layers that will be replaced with gate electrodes 130 (see FIG. 11) through a subsequent process. The sacrificial insulating layers 118 may be made of a different material from that of the interlayer insulating layers 120, and may be formed of a material which can be etched with etch selectivity under specific etching conditions with respect to the interlayer insulating layers 120. For example, the interlayer insulating layers 120 may be made of at least one of silicon oxide or silicon nitride, and the sacrificial insulating layers 118 may be made of a different material from that of the interlayer insulating layers 120 selected from silicon, silicon oxide, silicon carbide, and silicon nitride. A relatively thick intermediate interlayer insulating layer 125 may be formed on an uppermost portion of the first molded structure KS1. However, in embodiments, thicknesses of the interlayer insulating layers 120 may not all be the same. The thicknesses of the interlayer insulating layers 120 and the sacrificial insulating layers 118 and the number of films constituting them may be variously changed from those illustrated.

The vertical sacrificial layers 119 may be formed in a region corresponding to first channel structures CHI of FIG. 10. The vertical sacrificial layers 119 may be formed by forming lower channel holes (i.e., openings) to penetrate the first molded structure KS1, then depositing a material forming the vertical sacrificial layers 119 in the lower channel holes, and performing a planarization process. The vertical sacrificial layers 119 may include a different material from those of the interlayer insulating layers 120 and the sacrificial insulating layers 118. For example, the vertical sacrificial layers 119 may include a semiconductor material such as polycrystalline silicon, a silicon-based insulating material, or a carbon-based material.

Next, a cell region insulating layer 190 covering a laminated structure of the sacrificial insulating layers 118 and the interlayer insulating layers 120 may be partially formed. The term “covering” (or “cover,” or like terms), as may be used herein, is intended to broadly refer to an element, structure or layer that is on or over another element, structure or layer, either directly or with one or more other intervening elements, structures or layers therebetween.

Referring to FIG. 1, FIG. 3A and FIG. 3B, channel holes CHH penetrating (i.e., extending in) the first and second molded structures KS1 and KS2 in the Z-direction may be formed (S120), and channel layers 140 penetrating the first and second molded structures KS1 and KS2 may be formed in the channel holes CHH (S130).

First, upper separation regions US including an upper separation insulating layer 103 may be formed in the second molded structure KS2 by removing portions of the sacrificial insulating layers 118 and the interlayer insulating layers 120; that is, the upper separation regions US may extend in the Z-direction partially into the second molded structure KS2. A region where the upper separation regions US are to be formed may be exposed using a separate mask layer, predetermined numbers of the sacrificial insulating layers 118 and the interlayer insulating layers 120 may be removed from an uppermost portion thereof, and then an insulating material may be deposited to form the upper separation insulating layer 103. The upper separation insulating layer 103 may include silicon oxide, silicon nitride, or silicon oxynitride, although embodiments are not limited thereto.

The channel holes CHH may be formed by anisotropically etching the first and second molded structures KS1 and KS2 using the mask layer. Due to a height of the laminated structure, sidewalls of the channel holes CHH may not be perpendicular to the upper surface of the plate layer 101. The channel holes CHH may be formed to recess a portion of the plate layer 101.

Before forming channel layers 140 in the channel holes CHH (S130), channel dielectric layers 150 may formed along inner walls of the channel holes CHH; that is, the channel dielectric layers 150 may conformally cover the inner walls of the channel holes CHH. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The channel dielectric layers 150 may be formed by sequentially depositing a blocking layer 152, a charge storage layer 154, and a tunneling layer 156 in the channel holes CHH. The channel dielectric layers 150 may be formed to have a uniform thickness using, for example, an atomic layer deposition (ALD) or chemical vapor deposition (CVD) process.

The blocking layer 152 may include silicon oxide (SiO₂), silicon nitride (Si₃N₄), silicon oxynitride (SiON), a high-κ dielectric material, or a combination thereof. The charge storage layer 154 may be a charge trap layer or a floating gate conductive layer. The tunneling layer 156 may allow for charges to tunnel into the charge storage layer 154, and may include, for example, silicon oxide (SiO₂), silicon nitride (Si₃N₄), silicon oxynitride (SiON), or a combination thereof.

The channel layers 140 may be formed on the channel dielectric layers 150 in the channel holes CHH. In this operation, the channel layers 140 may be formed of an amorphous semiconductor material such as amorphous silicon or a polycrystalline semiconductor material such as polycrystalline silicon.

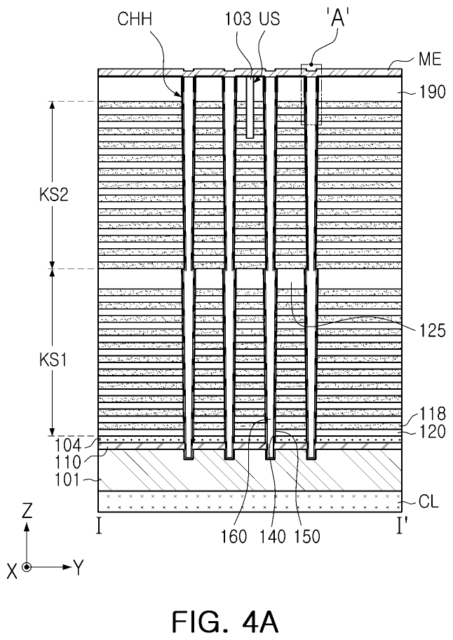

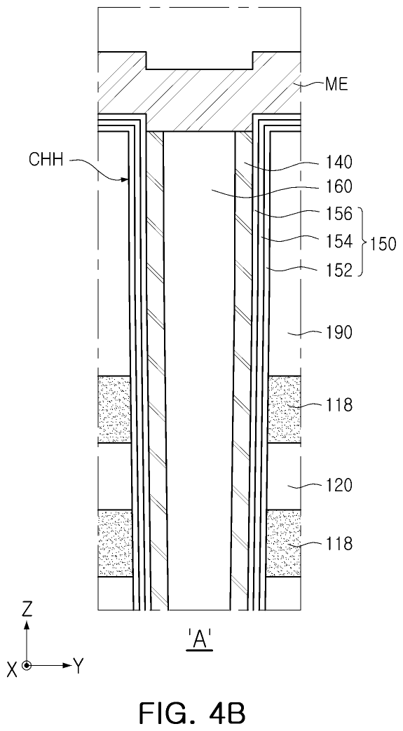

Referring to FIG. 1, FIG. 4A and FIG. 4B, channel-embedded insulating layers 160 may be formed in the channel holes CHH, and a metal layer ME may be formed on the channel holes CHH (S140).

The channel-embedded insulating layers 160 may be formed on the channel layers 140 to fill the channel holes CHH. Next, materials forming the channel layers 140 and the channel-embedded insulating layers 160 on an upper surface of the cell region insulating layer 190 may be partially removed by a chemical mechanical polishing (CMP) process, etc., so that an upper surface of the channel-embedded insulating layers 160 are coplanar with an upper surface of the channel layers 140, and then the metal layer ME may be formed. The metal layer ME may extend in a horizontal direction, and may be in contact with upper surfaces of the channel layers 140. The channel-embedded insulating layer 160 may include an insulating material, and may include, for example, silicon oxide (SiO₂), silicon nitride (Si₃N₄), silicon oxynitride (SiON), or a combination thereof. The metal layer ME may include, for example, nickel (Ni), titanium (Ti), cobalt (Co), tungsten (W), platinum (Pt), palladium (Pd), or a combination thereof. In an embodiment, the metal layer ME may include nickel (Ni).

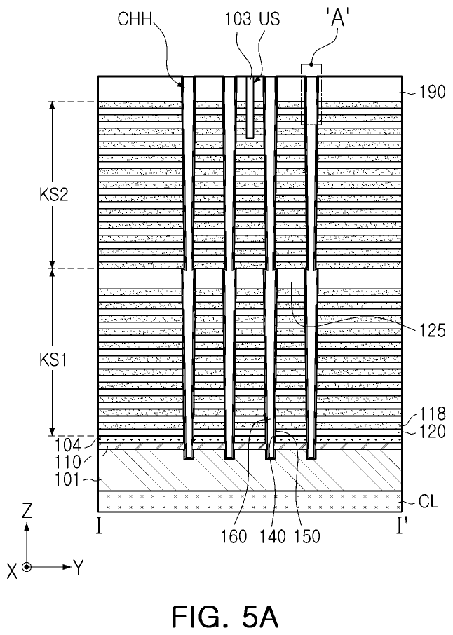

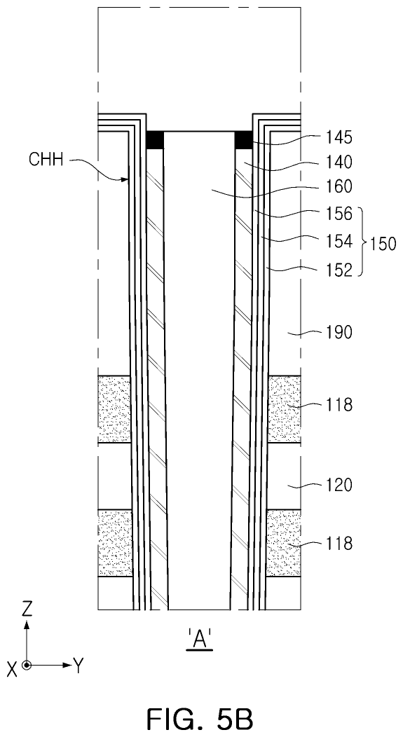

Referring to FIG. 1, FIG. 5A and FIG. 5B, metal silicide layers 145 may be formed on the upper surface of the channel layers 140 using the metal layer ME (S150).

The operation of forming the metal silicide layers 145 may include an operation of injecting metal from the metal layer ME into the channel layers 140, an operation of removing the remaining (i.e., unreacted) metal layer ME, and an operation of performing a silicidation process. The operation of injecting metal from the metal layer ME into the channel layers 140 may be an operation of applying heat at a temperature of about 200 to about 300° C. to inject metal elements into the channel layers 140. The operation of performing the silicidation process may be performed at a temperature of about 400° C. to about 500° C., and may form the metal silicide layers 145 having a composition of MSi₂ (where M is a metal element). In an embodiment, the operation of forming the conductive layer CL below the plate layer 101 (S100) may be performed after forming the metal silicide layers 145.

The metal silicide layer 145 may include a semiconductor element and a metal element. The metal silicide layer 145 may include, for example, nickel silicide (NiSi₂), titanium silicide (TiSi₂), cobalt silicide (CoSi₂), tungsten silicide (WSi₂), platinum silicide (PtSi₂), palladium (PdSi₂) silicide, or other metal silicides, and may include germanium (Ge) or silicon germanium (SiGe) instead of silicon (Si). The metal silicide layer 145 may be, for example, nickel silicide, represented by NiS₂.

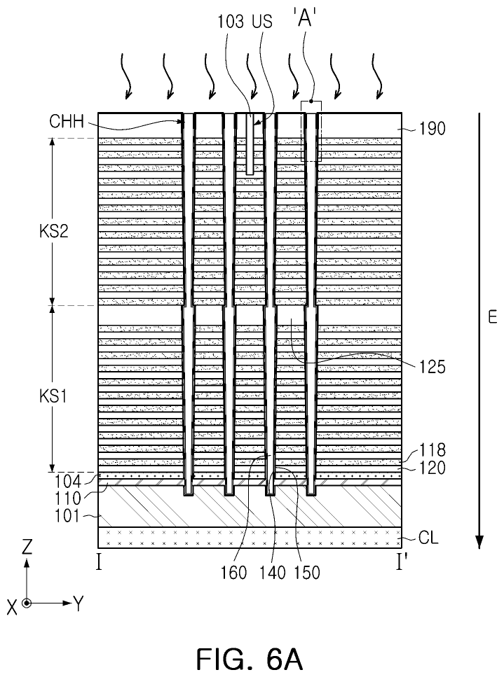

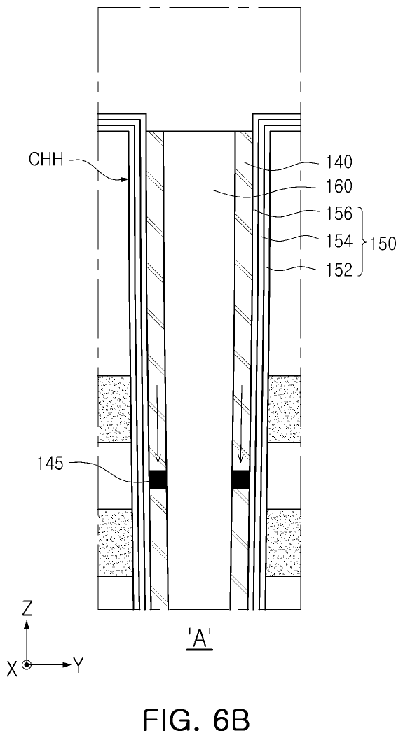

Referring to FIG. 1, FIG. 6A, and FIG. 6B, by applying an electric field E, the channel layers 140 may be crystallized using the metal silicide layers 145 (S160).

The channel layers 140 may be crystallized by a metal induced lateral crystallization (MILC) method by the metal silicide layers 145, and crystallization may occur from the tops (i.e., upper surface) of the channel layers 140. As a result, the channel layers 140 may have a single crystal or single crystal-like structure.

In an embodiment, the electric field E may be applied in a Z-direction, which is a direction perpendicular to the upper surface of the plate layer 101. For example, the electric field E may have a first direction (for example, −Z-direction) from the tops of the channel layers 140 toward bottoms of the channel layers 140. However, the present inventive concept is not limited thereto, and in some embodiments, the electric field E may have a direction (+Z-direction) from the bottoms of the channel layers 140 to the tops of the channel layers 140. In an embodiment, the direction of the electric field E may be changed multiple times in the +Z-direction or the −Z-direction over time.

In an embodiment, a heating process for heating the channel layers 140 may be further performed together with the process of crystallizing the channel layers 140 (S160). The heating process may be performed at a temperature range of about 500° C. to about 580° C. The heating process may be performed as a single type performed on one wafer, rather than a batch type performed on multiple wafers such as the plate layer 101.

The metal silicide layers 145 may move downward along the amorphous or polycrystalline channel layers 140 and be fixed in a lower region including the bottoms of the channel layers 140, while crystallizing the channel layers 140. The metal silicide layer 145 may remain as one particle in each of the channel layers 140. After the crystallization is performed, the metal silicide layers 145 may be located on a level lower than a lower surface of a lowermost one of the sacrificial insulating layers 118, and in an embodiment, may be located on a level lower than an upper surface of the first horizontal conductive layer 104.

According to embodiments of the present disclosure, since the electric field E is applied in a vertical direction, diffusion of the metal included in the metal silicide layers 145 may be facilitated, and a time taken for the crystallization process by the MILC method may be shortened. Therefore, a productivity of the method of manufacturing the semiconductor device may be improved.

When the above heating process is performed at a temperature exceeding about 580° C., nucleation of crystals may occur in the channel layers 140 due to a high temperature. In this case, a single crystal region may be partially formed inside the channel layers 140, and the MILC by the metal silicide layers 145 may be terminated in the single crystal region. Therefore, the channel layers 140 may not be crystallized in a lower portion of the single crystal region. However, according to embodiments of the present disclosure, since the heating process is performed at a relatively low temperature of about 580° C. or less, the nucleation of crystals in the channel layers 140 may be prevented, and crystallization may be performed throughout the channel layers 140. Therefore, deterioration of electrical characteristics of the semiconductor device may be prevented, and a defect rate may be reduced. In an embodiment, an interconnection structure such as a peripheral circuit may be formed before forming the molded structure KS1 and KS2, and according to embodiments of the present disclosure, since the heating process for crystallizing the channel layers 140 is performed at a relatively low temperature, deterioration of the interconnection structure may be prevented.

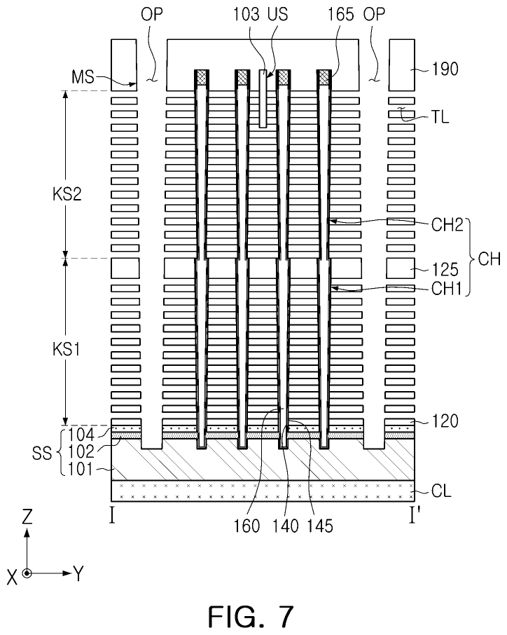

Referring to FIG. 1 and FIG. 7, channel pads 165 may be formed in the channel holes CHH (see FIGS. 6A and 6B) to form channel structures CH, openings OP penetrating (i.e., extending in) the first and second molded structures KS1 and KS2 in the Z-direction may be formed (S170), and after forming a second horizontal conductive layer 102, the sacrificial insulating layers 118 may be removed to form tunnel portions TL (S180).

The channel pads 165 may be formed after partially removing the channel layers 140 from the tops of the channel holes CHH (see FIGS. 6A and 6B). The channel pads 165 may be made of a conductive material such as silicon. However, depending on embodiments, the channel pads 165 may not be formed as a separate process, but may be formed as a part of the formation of the channel layers 140. As a result, the channel structures CH including the channel layers 140, the metal silicide layers 145, the channel dielectric layers 150, the channel buried insulating layer 160, and the channel pads 165 may be formed.

The channel structures CH each may form one memory cell string, and may be spaced apart from each other while forming rows and columns on the plate layer 101. The channel structures CH may be disposed to form a grid pattern in an X-Y plane (i.e., when viewed in a plan view), or may be disposed in a zigzag shape in one direction. The channel structures CH may be in a shape of a pillar filling the channel hole, and may have an inclined side surface that becomes narrower as it extends in the Z-direction toward the plate layer 101 depending on an aspect ratio.

After additionally forming the cell region insulating layer 190 on the channel structures CH, the openings OP may be formed. The openings OP may be formed to penetrate the first and second molded structures KS1 and KS2, penetrate the first horizontal conductive layer 104 from a lower portion thereof, and extend in the X-direction.

Next, separate sacrificial spacer layers may be formed in the openings OP, an etch-back process may be performed to expose the horizontal sacrificial layer 110 (see FIG. 6A), and the horizontal sacrificial layer 110 may be removed from the exposed region. The horizontal sacrificial layer 110 may be removed, for example, by a wet etching process. During a process of removing the horizontal sacrificial layer 110, a portion of the channel dielectric layer (150 in FIG. 6B) exposed in a region where the horizontal sacrificial layer 110 is removed may also be removed. After forming the second horizontal conductive layer 102 by depositing a conductive material in the region where the horizontal sacrificial layer 110 is removed, the sacrificial spacer layers may be removed in the openings OP. By this process, a source structure SS including the plate layer 101 and the first and second horizontal conductive layers 104 and 102, respectively, may be formed. The source structure SS may function as a common source line of a semiconductor device 100 described below. As illustrated in an enlarged view of FIG. 11, the second horizontal conductive layer 102 may be directly connected to the channel layer 140 around the channel layer 140. The second horizontal conductive layer 102 may partially extend in the Z-direction along the channel layer 140 and come into contact with the channel layer 140.

The first and second horizontal conductive layers 104 and 102, respectively, may include a semiconductor material, such as polycrystalline silicon. In this case, at least the second horizontal conductive layer 102 may be a layer doped with impurities of the same conductivity type as the plate layer 101. The first horizontal conductive layer 104 may be a doped layer or an intrinsic semiconductor layer including impurities diffused from the second horizontal conductive layer 102. However, the material of the first horizontal conductive layer 104 is not limited to a semiconductor material, and may be replaced with an insulating layer depending on embodiments. In example embodiments, a relatively thin insulating layer may be interposed between an upper surface of the second horizontal conductive layer 102 and a lower surface of the first horizontal conductive layer 104. This may be a portion of the horizontal sacrificial layer 110 that remains without being removed.

The sacrificial insulating layers 118 may be selectively removed relative to the interlayer insulating layers 120, for example, using wet etching. Accordingly, a plurality of tunnel portions TL may be formed between the interlayer insulating layers 120.

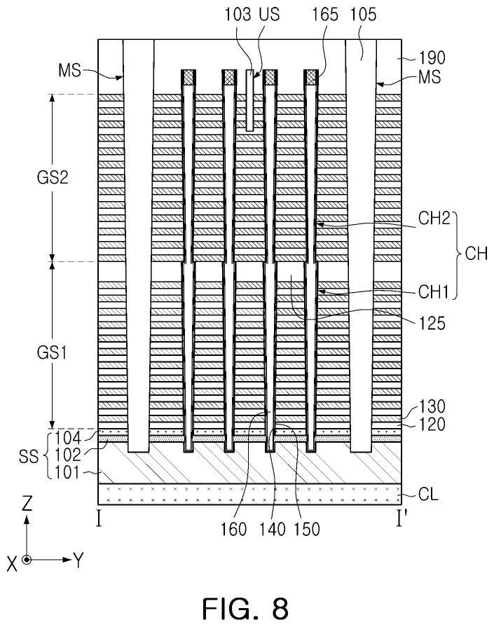

Referring to FIG. 1 and FIG. 8, a conductive material may be filled in the tunnel portions TL to form gate electrodes 130 where the sacrificial insulating layers 118 were previously disposed (S190), and separation regions MS including a separation insulating layer 105 may be formed. The separation regions MS may extend in the Z-direction through the first and second stack structures GS1, GS2.

First, a horizontal blocking layer 158 (see FIG. 11) may be formed in the tunnel portions TL. The horizontal blocking layer 158 may include silicon oxide (SiO₂), silicon nitride (Si₃N₄), silicon oxynitride (SiON), a high dielectric constant (high-κ) dielectric material, or a combination thereof. The conductive material forming the gate electrodes 130 may fill the tunnel portions TL. The conductive material may include a metal, polycrystalline silicon, or a metal silicide material. After forming the gate electrodes 130, the conductive material deposited in the openings OP may be removed by means of an additional process, and then the separation insulating layer 105 may be formed.

The separation regions MS may penetrate the gate electrodes 130, the interlayer insulating layers 120, and the first and second horizontal conductive layers 102 and 104 and may extend in the X-direction, and may be connected to the plate layer 101. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. The separation regions MS may separate the gate electrodes 130 from each other along the Y-direction. The separation regions MS may have a shape defined by a width that decreases as the separation regions MS extend in the Z-direction toward the plate layer 101 due to a high aspect ratio. The separation insulating layer 105 may include an insulating material, such as silicon oxide, silicon nitride, or silicon oxynitride, although embodiments are not limited thereto.

The gate electrodes 130 may be vertically spaced apart and stacked on the plate layer 101 to form the first and second stack structures GS1 and GS2. The gate electrodes 130 may include a lower gate electrode forming a gate of a ground selection transistor, memory gate electrodes on the lower gate electrode forming a plurality of memory cells, and upper gate electrodes on the memory gate electrodes forming gates of string selection transistors. The number of the memory gate electrodes forming the memory cells may be determined depending on a capacity of the semiconductor device 100. According to an embodiment, the upper and lower gate electrodes may be one or two or more, respectively, and may have the same as or different structure from the memory gate electrodes. In example embodiments, the gate electrodes 130 may further include a gate electrode 130 forming an erase transistor disposed above the upper gate electrodes and/or below the lower gate electrode and used for an erase operation using a gate induced drain leakage (GIDL) phenomenon. In addition, some of the gate electrodes 130, for example, gate electrodes adjacent to the upper or lower gate electrode, may be dummy gate electrodes.

The gate electrodes 130 may include a metal material such as tungsten (W). Depending on an embodiment, the gate electrodes 130 may include polycrystalline silicon or a metal silicide material. In example embodiments, the gate electrodes 130 may further include a diffusion barrier, and the diffusion barrier may include tungsten nitride (WN), tantalum nitride (TaN), titanium nitride (TiN), or a combination thereof, for example.

Referring to FIG. 1 and FIGS. 9 to 11, contact plugs 170 extending in the cell region insulating layer 190 and electrically connected to the channel structures CH may be formed, and the conductive layer CL (see FIG. 8) may be removed (S200), thereby manufacturing the semiconductor device 100.

The contact plugs 170 may electrically connect the channel structures CH to upper interconnection structures, such as bit lines. The contact plugs 170 may be made of a conductive material, and may include, for example, at least one of tungsten (W), aluminum (Al), or copper (Cu).

The conductive layer CL may be removed by performing a wet etching process or a planarization process. In an embodiment, the process of removing the conductive layer CL (S200) may be performed after the process of crystallizing the channel layers 140 (S160) and before the process of forming the openings OP penetrating the first and second molded structures KS1 and KS2 (S170).

As illustrated in FIG. 11, the metal silicide layer 145 may be located at least on a level lower than a lower surface of a lowermost first gate electrode 130L1 in the Z-direction, relative to the upper surface of the plate layer 101 as a reference. In some embodiments, when a first (i.e., lowermost) gate electrode 130L1 is a dummy gate electrode, the metal silicide layer 145 may be located at least on a level lower than a lower surface of a second gate electrode 130L2 above the first gate electrode 130L1. For example, the metal silicide layer 145 may be located in a fixed region SR including a bottom of the channel layer 140. The fixed region SR may be a region from a lower surface of the channel layer 140 to an upper surface of the first horizontal conductive layer 104. The metal silicide layer 145 may be located on a level lower than the upper surface of the first horizontal conductive layer 104. At least one metal silicide layer 145 may be located for each channel structure CH.

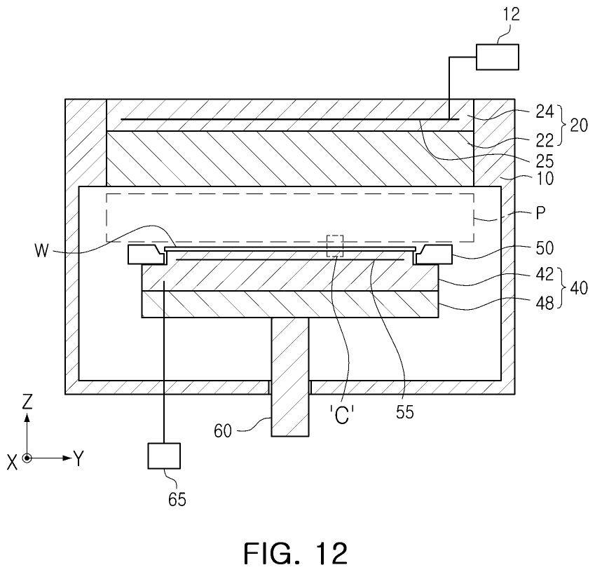

FIGS. 12 to 14 are drawings illustrating a method for crystallizing a channel layer according to an example embodiment

Referring to FIG. 12, the process of crystallizing the channel layers 140 (S160) may be performed in a plasma chamber 10.

The plasma chamber 10 may provide a space sealed from an outside environment for a semiconductor wafer W. The plasma chamber 10 may be made of a metal material such as aluminum (Al), and in an example embodiment, the plasma chamber 10 may include a substrate passage through which the semiconductor wafer W is introduced or removed. The plasma chamber 10 may be, for example, a capacitively coupled plasma (CCP) chamber, an inductively coupled plasma (ICP) chamber, or a microwave plasma chamber.

An upper electrode 20 may be disposed in an upper portion of the plasma chamber 10, and may be disposed on (i.e., above or over) the semiconductor wafer W so as to face the semiconductor wafer W. The upper electrode 20 may include a shower head 22 and an upper plate 24 on the shower head 22. The shower head 22 may be introduced with process gas and discharge the process gas onto the semiconductor wafer W in the plasma chamber 10.

A gas distribution structure (not explicitly shown, but implied) supplying the process gas to the shower head 22 and a cooler or heater (not explicitly shown, but implied) which may control a temperature of the shower head 22 may be embedded in the upper plate 24. In addition, the upper plate 24 may include an electrode 25 embedded in the upper plate 24 and electrically connected to a power supply 12 outside the plasma chamber 10. The upper electrode 20 may interact with a lower electrode 40 supporting the semiconductor wafer W so as to form plasma P between the upper electrode 20 and the lower electrode 40.

The lower electrode 40 may be disposed in the plasma chamber 10 and include an electrostatic chuck 42 supporting the semiconductor wafer W and a lower plate 48 supporting the electrostatic chuck 42.

The electrostatic chuck 42 may be an upper member of the lower electrode 40 that supports the semiconductor wafer W, and a lift 60 may be vertically raised or lowered to adjust a distance of the semiconductor wafer W from the shower head 22. The electrostatic chuck 42 may be a susceptor including a heating pattern 55, and the heating pattern 55 may be electrically connected to a power supply outside the plasma chamber 10, and the susceptor may be heated using power supplied from the power supply. The susceptor may be made of a ceramic material such as aluminum nitride (AlN) or aluminum oxide (Al₂O₃).

The electrostatic chuck 42 may be connected to a power supply 65 outside the plasma chamber 10. When plasma gas is ejected from the shower head 22 and high frequency is applied to the upper electrode 20 and the lower electrode 40 using the power supply 12 and the power supply 65, the plasma P may be generated between the upper electrode 20 and the lower electrode 40. In an embodiment, the voltage applied to the upper plate 24 and the electrostatic chuck 42 may be a DC (direct current) voltage and/or an AC (alternating current) voltage. For example, only a DC voltage may be applied to the upper plate 24 and the electrostatic chuck 42, or both a DC voltage and an AC voltage may be applied thereto.

An edge ring 50 provided on an outer side of a perimeter of an edge of the semiconductor wafer W may be further disposed in the plasma chamber 10 of the present disclosure. The edge ring 50 may be arranged to surround the semiconductor wafer W at an edge region of the electrostatic chuck 42, and may prevent the plasma P generated by the upper electrode 20 and the lower electrode 40 in the plasma process from being concentrated on the edge region of the wafer W so as to play a role in maintaining uniform plasma. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The edge ring 50 may be made of various materials as needed. In an example embodiment, the edge ring 50 may be made of an opaque material such as silicon, silicon carbide or ceramic, or a transparent material such as quartz. The edge ring 50 may be lifted and lowered by a lifting pin (not shown), and may be replaced as needed.

FIG. 12 illustrates a structure of the plasma chamber 10 when the plasma chamber 10 is a capacitively coupled plasma chamber, and the structure of the plasma chamber 10 may vary depending on the embodiments.

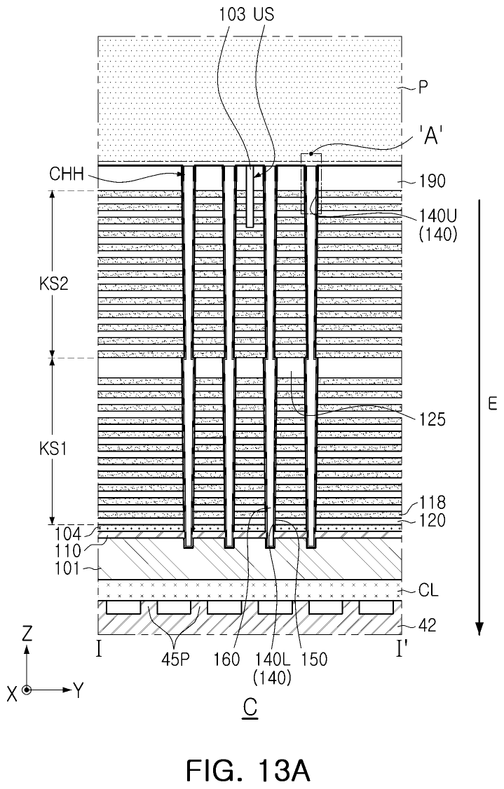

FIG. 13A may correspond to region C of FIG. 12, and FIG. 13B may correspond to region A of FIG. 13A.

Referring to FIG. 13A and FIG. 13B, the semiconductor wafer W having a horizontal sacrificial layer 110, a first horizontal conductive layer 104, first and second molded structures KS1 and KS2, and a cell region insulating layer 190 formed on an upper surface thereof may be disposed on the electrostatic chuck 42. The semiconductor wafer W may include a plate layer 101. For example, the semiconductor wafer W may be a bulk wafer including a semiconductor material, and the plate layer 101 may constitute at least a portion of the semiconductor wafer W. A conductive layer CL may be disposed on a lower surface of the semiconductor wafer W. As described above with reference to FIG. 6A and FIG. 6B, an electric field E may be applied to the semiconductor wafer W. The electric field E may cause current to flow from upper portions 140U of the channel layers 140 to lower portions 140L of the channel layers 140, which may facilitate diffusion of a metal included in silicide layers 145. Therefore, time taken by a crystallization process may be shortened by an MILC method. The process of crystallizing the channel layers 140 (S160) may be performed in a chamber that is the same as or different from the chamber in which the process of forming the metal silicide layers 145 (S150) is performed. In an embodiment, after forming the metal silicide layers 145, the semiconductor wafer W may be returned into the plasma chamber 10 and located on the electrostatic chuck 42.

Specifically, the electric field E may be formed between the plasma P and the conductive layer CL. The plasma P formed in the plasma chamber 10 may cover structures on the wafer W. For example, the plasma P may come into contact with the channel layers 140, and a voltage may be applied to the channel layers 140. The term “cover” (or “covers,” or like terms), as may be used herein, is intended to broadly refer to an element, structure or layer that is on or over another element, structure or layer, either directly or with one or more other intervening elements, structures or layers therebetween. When an electrode material layer is formed on the channel layers 140 and the channel dielectric layers 150 and a voltage is directly applied to the electrode material layer, a contact region between the electrode material layer and the channel layers 140 may not be sufficient, and a contact resistance may increase. However, according to the embodiments of the present disclosure, since the plasma P comes into contact with the channel layers 140, the contact resistance between the plasma P and the channel layers 140 may be reduced, and the current flowing along the channel layers 140 may be increased. This may facilitate diffusion of the metal included in the silicide layers 145, and may shorten the crystallization process.

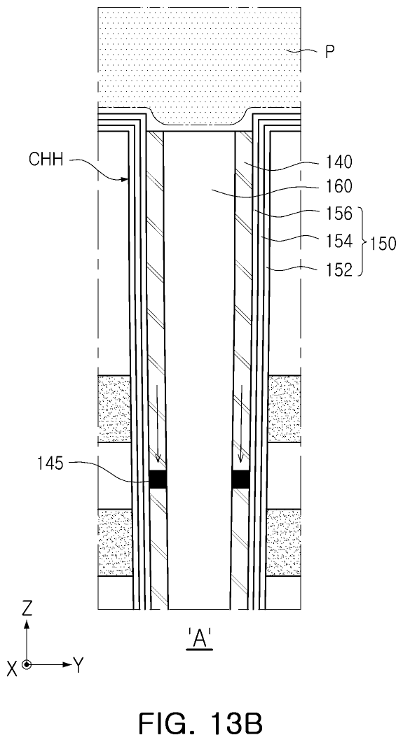

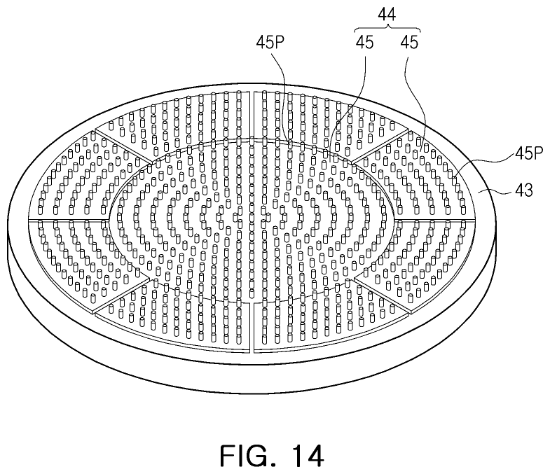

FIG. 14 illustrates an electrostatic chuck according to an example embodiment.

Referring to FIGS. 13A and 14, the conductive layer CL may be disposed between the plate layer 101 and the electrostatic chuck 42, and may be in contact with the electrostatic chuck 42. As illustrated in FIG. 14, the electrostatic chuck 42 may include a chuck table 44 on a support 43. The chuck table 44 may include a plurality of segmented plates 45. Each of the plurality of segmented plates 45 may include protrusions 45P protruding upward from its upper surface. In an embodiment, the electrostatic chuck 42 may include dimples extending downward from its upper surface.

When the electrostatic chuck 42 and the plate layer 101 are in contact with each other, a contact area between the electrostatic chuck 42 and the plate layer 101 may not be sufficient due to the protrusions 45P of the segmented plates 45, and the contact resistance may increase. However, according to embodiments of the present disclosure, the conductive layer CL covering a lower surface of the plate layer 101 may be disposed between the electrostatic chuck 42 and the plate layer 101. Since the conductive layer CL includes a conductive material, even if an electric field E of the same magnitude is applied, current may flow better in the conductive layer CL than in the plate layer 101 including a semiconductor material. For example, when the conductive layer CL is disposed on the lower surface of the plate layer 101, current flowing along the channel layers 140 may be increased, compared to when the conductive layer CL is not disposed. This may facilitate diffusion of the metal included in the silicide layers 145 and shorten the crystallization process.

In an embodiment, a difference in voltage between the conductive layer CL and the plasma P may be greater than 0 V and less than or equal to about 25 V. As described above, a heating process for heating the channel layers 140 may be further performed together with the process for crystallizing the channel layers 140 (S160). For example, power may be supplied to the heating pattern 55 of the electrostatic chuck 42 to heat the heating pattern 55, and thus the semiconductor wafer W and the channel layers 140 may be heated. The channel layers 140 may be heated by heat conduction and heat radiation from the heating pattern 55. In an embodiment, the plasma chamber 10 may not be in a vacuum state, and in this case, the channel layers 140 may be further heated by convection, thereby increasing heat transfer efficiency and shortening the process time. In an embodiment, the heating process may be performed at a pressure greater than 0 Torr and less than or equal to about 10 Torr. The heating process may be performed during a range of about 2 hours to about 8 hours.

Hereinafter, a crystallinity of the channel layers 140 according to comparative examples and inventive examples will be described. In the comparative examples and the inventive examples, metal plates were arranged above and below the channel layers 140 and the molded structures KS1 and KS2, and an electric field was applied to the channel layers 140 only in the inventive examples. In the comparative examples and the inventive examples, a moving distance of the metal silicide layers 145 along the channel layers 140 was observed.

TABLE 1

| | Comparative | Inventive | Comparative | Inventive |
|---|---|---|---|---|
| | Example 1 | Example 1 | Example 2 | Example 2 |
| Temperature, ° C. | 600 | 600 | 580 | 580 |
| Pressure, Torr | 8 | 8 | 8 | 8 |
| Voltage, V | 0 | 10 | 0 | 10 |
| Time, hr | 4 | 4 | 4 | 4 |

Referring to Table 1, both Comparative Example 1 and Inventive Example 1 were subjected to a heating process at a temperature of 600° C. and a pressure of 8 Torr for 4 hours. In the case of Inventive Example 1, a voltage of 10 V was applied to the metal plates. Both Comparative Example 2 and Inventive Example 2 were subjected to a heating process at a temperature of 580° C. and a pressure of 8 Torr for 4 hours. In the case of Inventive Example 2, a voltage of 10 V was applied to the metal plates. No significant difference was observed in the movement distances of the metal silicide layers 145 in Comparative Example 1 and Inventive Example 1. No significant difference was observed in the moving distances of the metal silicide layers 145 in Comparative Example 2 and Inventive Example 2.

TABLE 2

| | Comparative | Inventive | Inventive | Inventive |
|---|---|---|---|---|
| | Example 3 | Example 3 | Example 4 | Example 5 |
| Temperature, ° C. | 560 | 560 | 560 | 560 |
| Pressure, Torr | 8 | 8 | 8 | 8 |
| Voltage, V | 0 | 10 | 20 | 25 |
| Time, hr | 4 | 4 | 4 | 4 |

Referring to Table 2, in Comparative Example 3, Inventive Example 3, Inventive Example 4, and Inventive Example 5, a heating process was performed for 4 hours under conditions of a temperature of 560° C. and a pressure of 8 Torr with different voltages. In Comparative Example 3 (no voltage applied), the metal silicide layers 145 reaching the bottoms of the channel layers 140 were hardly observed. In Inventive Example 3, a moving distance of the channel layers 140 increased compared to Comparative Example 3, and in Inventive Examples 4 and 5, the number of metal silicide layers 145 reaching the bottoms of the channel layers 140 increased compared to Inventive Example 3.

TABLE 3

| | Comparative | Inventive | Inventive |
|---|---|---|---|
| | Example 4 | Example 6 | Example 7 |
| Temperature, ° C. | 560 | 560 | 560 |
| Pressure, Torr | 8 | 8 | 8 |
| Voltage, V | 0 | 10 | 25 |
| Time, hr | 8 | 8 | 8 |

Referring to Table 3, in Comparative Example 4, Inventive Example 6, and Inventive Example 7, the heating process was performed for 8 hours under the conditions of a temperature of 560° C. and a pressure of 8 Torr with different voltages. In Comparative Example 4 (no voltage applied), unlike Comparative Example 3, the metal silicide layers 145 reaching the bottoms of the channel layers 140 were observed. In Inventive Examples 6 and 7, the number of metal silicide layers 145 reaching the bottoms of the channel layers 140 increased compared to Comparative Example 4.

Upon examining the results in Table 2 and Table 3, even when an electric field is not applied, at least some of the metal silicide layers 145 may reach the bottoms of the channel layers 140 when the heating process is performed for a long time. However, as the electric field increases, the number of metal silicide layers 145 reaching the bottoms of the channel layers 140 increases.

TABLE 4

| | Comparative | Inventive | Inventive |
|---|---|---|---|
| | Example 5 | Example 8 | Example 9 |
| Temperature, ° C. | 540 | 540 | 540 |
| Pressure, Torr | 8 | 8 | 8 |
| Voltage, V | 0 | 10 | 20 |
| Time, hr | 4 | 4 | 4 |

Referring to Table 4, in Comparative Example 5, Inventive Example 8, and Inventive Example 9, the heating process was performed for 4 hours under conditions of a temperature of 540° C. and a pressure of 8 Torr with different voltages. In Comparative Example 5, the metal silicide layers 145 reaching the bottoms of the channel layers 140 were hardly observed. In Inventive Examples 8 and 9, the moving distance of the channel layers 140 increased compared to Comparative Example 5.

TABLE 5

| | Comparative Example 6 | Inventive Example 10 |
|---|---|---|
| Temperature, ° C. | 540 | 540 |
| Pressure, Torr | 8 | 8 |
| Voltage, V | 0 | 25 |
| Time, hr | 8 | 8 |

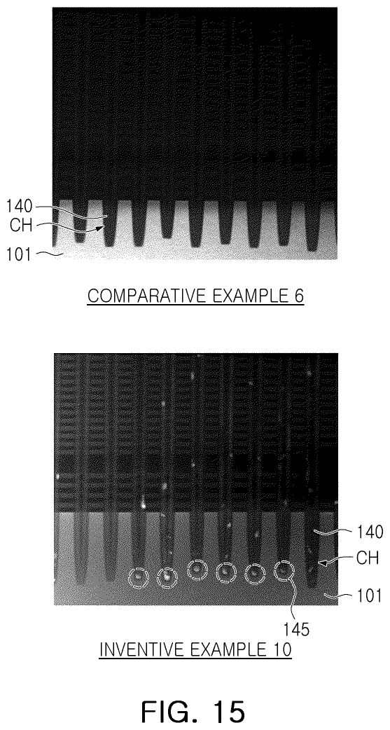

FIG. 15 is a vertical cross-sectional view illustrating the channel layers according to a comparative example and an inventive example. Specifically, FIG. 15 illustrates the results of Comparative Example 6 and Inventive Example 10 shown in Table 5 above.

Referring to FIG. 15 and Table 5, in Comparative Example 6 and Inventive Example 10, a heating process was performed under conditions of a temperature of 540° C. and a pressure of 8 Torr for 8 hours with different voltages. In Comparative Example 6 (no voltage applied), the metal silicide layers 145 reaching the bottoms of the channel layers 140 were hardly observed. In Inventive Example 10 (25 volts applied), a significant number of metal silicide layers 145 reached the bottoms of the channel layers 140.

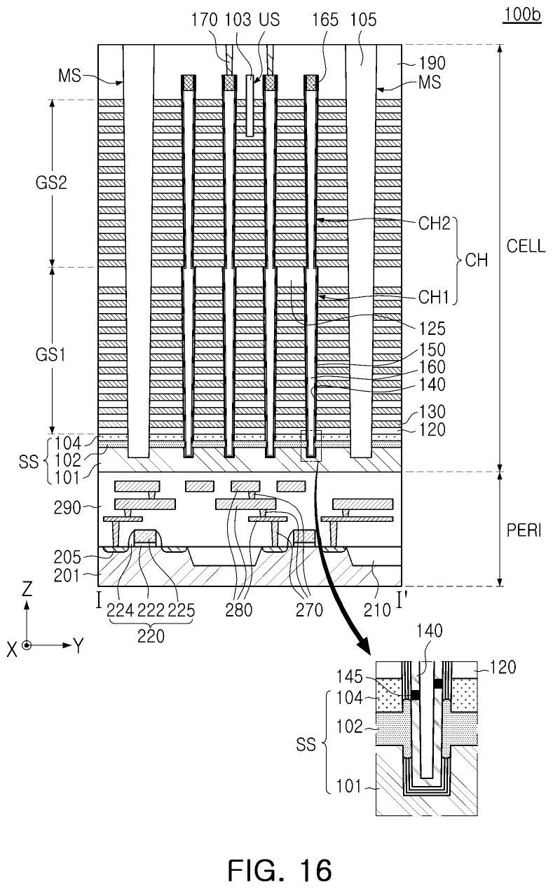

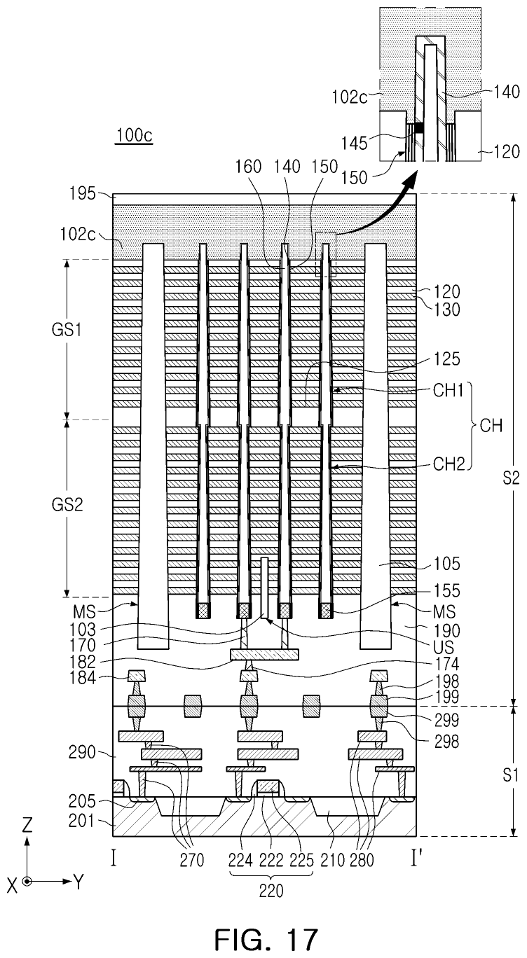

FIG. 16 and FIG. 17 are schematic vertical cross-sectional views of semiconductor devices according to example embodiments.

Referring to FIG. 16, a semiconductor device 100b may include a memory cell region CELL and a peripheral circuit region PERI that are stacked vertically. The memory cell region CELL may be disposed on the peripheral circuit region PERI. For example, in the case of the semiconductor device 100 of FIG. 10, the peripheral circuit region PERI may be disposed on the plate layer 101 in a region not shown, or the peripheral circuit region PERI may be disposed therebelow as in the semiconductor device 100b of the present embodiment. In example embodiments, the memory cell region CELL may be disposed below the peripheral circuit region PERI. The description with reference to FIGS. 9 to 11 may be similarly applied to the memory cell region CELL.

The peripheral circuit region PERI may include a base substrate 201, circuit elements 220 disposed on the base substrate 201, circuit contact plugs 270, and circuit interconnection lines 280.

The base substrate 201 may have an upper surface extending in an X-direction and a Y-direction. The base substrate 201 may have element separation layers 210 (e.g., interlayer dielectric layer (ILD) structures) formed to define one or more active regions. Source/drain regions 205 containing impurities may be disposed in a portion of the active region. The base substrate 201 may include a semiconductor material, such as a group IV semiconductor, a group III-V compound semiconductor, or a group II-VI compound semiconductor. The base substrate 201 may be provided as a bulk wafer or an epitaxial layer. In the present embodiment, an upper plate layer 101 may be provided as a polycrystalline semiconductor layer, such as a polycrystalline silicon layer, or an epitaxial layer.

The circuit elements 220 may include a horizontal (i.e., lateral) transistor. Each of the circuit elements 220 may include a circuit gate dielectric layer 222, a circuit gate electrode 225, and a spacer layer 224 disposed on opposing sides of the circuit gate electrode 225 and circuit gate dielectric layer 222. The source/drain regions 205 may be disposed in the base substrate 201 on both (i.e., opposing) sides of the circuit gate electrode 225.

A peripheral region insulating layer 290 may be disposed on the circuit element 220 on the base substrate 201. The circuit contact plugs 270 may penetrate the peripheral region insulating layer 290 and be connected to the source/drain regions 205. Electrical signals may be applied to the circuit elements 220 by the circuit contact plugs 270. In a region not shown, the circuit contact plugs 270 may also be connected to the circuit gate electrode 225. The circuit interconnection lines 280 may be connected to the circuit contact plugs 270, and may be disposed in multiple layers.

In the semiconductor device 100b, the peripheral circuit region PERI may be manufactured first, and then the plate layer 101 of the memory cell region CELL may be formed thereon, thereby manufacturing the memory cell region CELL. After the process of forming the peripheral circuit region PERI, a process of forming a conductive layer CL below the plate layer 101 (S100) may be performed. For example, the conductive layer CL may be formed on a lower surface of the base substrate 201 of the peripheral circuit region PERI. The process of removing the conductive layer CL (S200) may be performed after forming the gate electrodes 130 (S190) and forming the memory cell region CELL.

The plate layer 101 may have the same size (e.g., in the Y-direction) as the base substrate 201, or may be formed smaller than the base substrate 201. The memory cell region CELL and the peripheral circuit region PERI may be connected to each other in a region not shown. For example, one end of the gate electrode 130 in the Y-direction may be electrically connected to the circuit elements 220. The form in which the memory cell region CELL and the peripheral circuit region PERI are vertically stacked in this way may be applied to other embodiments as well.

Referring to FIG. 17, a semiconductor device 100c may include a first semiconductor structure S1 and a second semiconductor structure S2 which are bonded by a wafer bonding method or other attachment means.

The description of the peripheral circuit region PERI detailed above with reference to FIG. 16 may be applied to the first semiconductor structure S1. However, the first semiconductor structure S1 may further include first bonding vias 298 and first bonding pads 299, which are bonding structures. The first bonding vias 298 may be disposed on an uppermost circuit interconnection lines 280, and may be connected to the circuit interconnection lines 280. At least a portion of the first bonding pads 299 may be connected to the first bonding vias 298 on the first bonding vias 298. The first bonding pads 299 may be connected to second bonding pads 199 of the second semiconductor structure S2. The first bonding pads 299 may provide an electrical connection path according to a bonding of the first semiconductor structure S1 and the second semiconductor structure S2, together with the second bonding pads 199. The first bonding vias 298 and the first bonding pads 299 may include a conductive material such as copper (Cu).

With respect to the second semiconductor structure S2, unless otherwise described, the description with reference to FIGS. 9 to 11 may be similarly applied. The second semiconductor structure S2 may further include first and second cell interconnection lines 182 and 184 and vias 174, which are interconnection structures, and may further include second bonding vias 198 and the second bonding pads 199, which are bonding structures. The second semiconductor structure S2 may further include an upper substrate 102c covering a first stacked structure GS1 and a protective layer 195 covering an upper surface of the upper substrate 102c.

The upper substrate 102c may cover a separation insulating layer 105, a channel structure CH, and an uppermost interlayer insulating layer 120 of the first stacked structure GS1. One end of a channel layer 140 may not be covered by a gate dielectric layer 150, and may be in contact with the upper substrate 102c. The upper substrate 102c may have an upper surface extending in an X-direction and a Y-direction. The upper substrate 102c may include a semiconductor material, such as a group IV semiconductor, a group III-V compound semiconductor, or a group II-VI compound semiconductor. For example, the group IV semiconductor may include silicon, germanium, or silicon-germanium. The upper substrate 102c may further include impurities. The upper substrate 102c may be provided as a polycrystalline semiconductor layer, such as a polycrystalline silicon layer, or an epitaxial layer. The upper substrate 102c may function as a common source line of the semiconductor element 100c.

The first cell interconnection line 182 may be connected to the contact plugs 170, and the via 174 may connect the first and second cell interconnection lines 182 and 184 to each other. However, in embodiments, the number of layers and arrangement forms of the contact plugs, the vias and the interconnection lines forming the interconnection structure may be variously changed. The first and second cell interconnection lines 182 and 184 and the via 174 may be made of a conductive material, and may include, for example, at least one of tungsten (W), aluminum (Al), or copper (Cu).

The second bonding vias 198 and the second bonding pads 199 may be disposed below the lowermost second cell interconnection lines 184. The second bonding vias 198 may be connected to the second cell interconnection lines 184 and the second bonding pads 199, and the second bonding pads 199 may be bonded to the first bonding pads 299 of the first semiconductor structure S1. The second bonding vias 198 and the second bonding pads 199 may include a conductive material such as copper (Cu).

The first semiconductor structure S1 and the second semiconductor structure S2 may be bonded by a copper-copper (Cu—Cu) bonding by the first bonding pads 299 and the second bonding pads 199. In addition to the copper-copper (Cu—Cu) bonding, the first semiconductor structure S1 and the second semiconductor structure S2 may be bonded by a dielectric-dielectric bonding. The dielectric-dielectric bonding may be a bonding by dielectric layers forming a portion of each of the peripheral region insulating layer 290 and the cell region insulating layer 190 and surrounding each of the first bonding pads 299 and the second bonding pads 199. Thereby, the first semiconductor structure S1 and the second semiconductor structure S2 may be bonded without a separate adhesive layer.

The process of bonding the first semiconductor structure S1 and the second semiconductor structure S2 may be performed after the process of forming the gate electrodes 130 (S190) and the process of removing the conductive layer CL (S200). For example, the first semiconductor structure S1 may be formed first, and the processes of the operations S100 to S190 described with reference to FIGS. 2 to 11 may be performed. Thereafter, the plate layer 101 may be removed together with the process of removing the conductive layer CL (S200). The plate layer 101 may be removed to expose the separation insulating layers 105 and the channel structures CH, and gate dielectric layers 150 may be partially etched to expose the channel layers 140. Thereafter, an upper substrate 102c may be formed to cover the channel layers 140, and a protective layer 195 may be formed on the upper substrate 102c to manufacture the second semiconductor structure S2. The semiconductor device 100c may be manufactured by bonding the first semiconductor structure S1 and the second semiconductor structure S2.

According to embodiments of the present inventive concept, a crystallization process of a channel layer using a metal silicide layer may be formed at a relatively low temperature, so that a formation of crystal nuclei in the channel layer may be prevented. In addition, since an electric field is applied to the channel layer, the crystallization process may be shortened, and a productivity of a semiconductor device manufacturing process may be improved.

While example embodiments have been shown and described above, it will be apparent to those skilled in the art that modifications and variations could be made without departing from the scope of the present inventive concept as defined by the appended claims.

What is claimed is:

1. A method of manufacturing a semiconductor device, comprising:
forming a conductive layer below a plate layer;
forming a molded structure on the plate layer;
forming channel layers extending in the molded structure in a first direction perpendicular to an upper surface of the plate layer;
forming a metal layer on the channel layers;
forming a metal silicide layer on an upper surface of each of the channel layers using the metal layer;
applying an electric field to crystallize the channel layers using the metal silicide layers; and
removing the conductive layer.

2. The method of claim 1, wherein the applying the electric field comprises forming plasma on the channel layers.

3. The method of claim 2, wherein the electric field is formed between the conductive layer and the plasma.

4. The method of claim 2, wherein a difference in voltage between the conductive layer and the plasma is greater than 0 volts (V) and less than or equal to about 25 V.

5. The method of claim 1, wherein the electric field causes a current to flow through the channel layers along the first direction.

6. The method of claim 5, wherein the electric field causes the current to flow from upper portions of the channel layers to lower portions of the channel layers.

7. The method of claim 1, further comprising:
performing a heating process for heating the channel layers when crystallizing the channel layers.

8. The method of claim 7, wherein the channel layers are heated in a range of about 500° C. to about 580° C.

9. The method of claim 7, wherein the heating process is performed for a duration of about 2 hours to about 8 hours.

10. The method of claim 7, wherein the heating process is performed at a pressure greater than 0 Torr and less than or equal to about 10 Torr.

11. The method of claim 1, wherein the metal layer comprises nickel (Ni), cobalt (Co), platinum (Pt), palladium (Pd), or a combination thereof.

12. The method of claim 1, wherein the conductive layer comprises at least one of a metal, a metal nitride, or a doped semiconductor material.

13. The method of claim 1, further comprising:
before forming the molded structure, forming a peripheral circuit region comprising one or more circuit elements,
wherein the conductive layer is formed on a lower surface of a base substrate of the peripheral circuit region, and
wherein the molded structure is formed on the peripheral circuit region.

14. The method of claim 1, further comprising:
forming a first semiconductor structure comprising one or more circuit elements; and
bonding a second semiconductor structure comprising the channel layers to the first semiconductor structure,
wherein the plate layer is removed when removing the conductive layer.

15. A method of manufacturing a semiconductor device, comprising:
forming a conductive layer below a plate layer;
forming a molded structure on the plate layer;
forming channel layers extending in the molded structure in a first direction perpendicular to an upper surface of the plate layer;
forming metal silicide layers on respective upper surfaces of the channel layers using the metal layer; and
applying an electric field to crystallize the channel layers using the metal silicide layers, wherein the applying the electric field comprises:
providing a wafer comprising the plate layer on an electrostatic chuck in a plasma chamber; and
applying a voltage to the electrostatic chuck and an upper electrode on the wafer to form plasma on the channel layers.

16. The method of claim 15, wherein the conductive layer is between the plate layer and the electrostatic chuck and is in contact with an upper surface of the electrostatic chuck.

17. The method of claim 15, wherein a DC (direct current) or AC (alternating current) voltage is applied to the electrostatic chuck.

18. The method of claim 15, further comprising:
performing a heating process using a heating pattern in the electrostatic chuck.

19. The method of claim 15, wherein the plasma chamber is a capacitively coupled plasma chamber, an inductively coupled plasma chamber, or a microwave plasma chamber.

20. A method of manufacturing a semiconductor device, comprising:
forming a conductive layer below a plate layer;
alternately stacking interlayer insulating layers and sacrificial insulating layers on the plate layer in a first direction perpendicular to an upper surface of the plate layer to form a molded structure;
forming channel holes extending in the first direction through the molded structure;
forming channel layers in the channel holes;
forming a metal layer on the channel layers;
forming a metal silicide layer on an upper surface of each of the channel layers using the metal layer;
heating the channel layers;
applying an electric field in the first direction to crystallize the channel layers using the metal silicide layers; and
removing the conductive layer.
